(19) United States
(12) Patent Application Publication
(10) Pub. No.: US 2025/0038069 A1
(43) Pub. Date: Jan. 30, 2025

(54) PACKAGING UNIT FOR DIRECT COOLING OF SEMICONDUCTOR DEVICE AND MANUFACTURING METHOD THEREOF

(71) Applicant: CHUNG-ANG UNIVERSITY INDUSTRY ACADEMIC COOPERATION FOUNDATION, Seoul (KR)

(72) Inventors: HYOUNG SOON LEE, Gyeonggi-do (KR); MIN SOO KANG, Seoul (KR); HAE CHEON KIM, Daejeon (KR); HYUN WOOK JUNG, Daejeon (KR); HO KYUN AHN, Daejeon (KR); JONG WON LIM, Daejeon (KR)

(21) Appl. No.: 18/919,732

(22) Filed: Oct. 18, 2024

Related U.S. Application Data
(62) Division of application No. 17/883,926, filed on Aug. 9, 2022.

(30) Foreign Application Priority Data
May 6, 2022 (KR) 10-2022-0055903

(51) Int. Cl. H01L 23/473; H01L 21/48; H01L 23/367; H01L 23/433

(52) U.S. Cl. CPC H01L 23/473; H01L 21/4871; H01L 23/3672; H01L 23/433

(57) ABSTRACT

In a method of manufacturing a packaging unit, a material layer is stacked for forming the semiconductor device on one surface of a substrate, a semiconductor device is formed by performing a semiconductor process on the material layer, a flow channel through which a cooling fluid flows is formed on the other surface of the substrate to enable direct cooling of the semiconductor device using the cooling fluid, a packaging block is disposed at a position spaced apart from the substrate for packaging of the semiconductor device, and an electrode placed on the packaging block is electrically connected to the semiconductor device, and a heat sink unit having a flow path forming portion in which a flow path communicating with the flow channel of the substrate is formed is arranged below the packaging block, and the substrate is combined with the heat sink unit.

### CROSS-REFERENCE TO RELATED APPLICATION AND CLAIM OF PRIORITY

This application is a divisional application of U.S. application Ser. No. 17/883,926, filed on Aug. 9, 2022, which claims priority to the benefit of Korean Patent Application No. 10-2022-0055903, filed on May 6, 2022 in the Korean Intellectual Property Office, the entire contents of which are incorporated herein by reference.

### BACKGROUND

### 1. Technical Field

The present disclosure relates to a packaging unit for direct cooling of a semiconductor device and a manufacturing method thereof, and more particularly, to an improved packaging unit for direct cooling of a semiconductor device that enables implementation of a direct cooling method by directly manufacturing a flow path of a liquid in a chip package of a device for thermal management of a high-output and high-heat semiconductor, and a manufacturing method thereof.

### 2. Background Art

As the size of electronic circuits is smaller and more integrated, research into a problem of heating of electronic devices and its solution has been conducted.

Because heating of a semiconductor device leads to performance degradation, interest in a heat sink and a heat dissipation device is increasing.

The existing heat dissipation device uses a method of attaching a heat dissipation structure on chip packaging using a thermal interfacial material (TIM), but the method is difficult to satisfy an increased output and its heat dissipation performance.

### SUMMARY

The present disclosure is directed to providing a packaging unit for direct cooling of a semiconductor device that enables direct cooling of a substrate on which a device is to be formed without using an indirect cooling method in which a heat sink is attached to a semiconductor device using a thermal interfacial material (TIM).

The present disclosure is also directed to providing a packaging unit for direct cooling of a semiconductor device that enables formation of a flow path structure for implementing device direct cooling by using a configuration used for packaging of the semiconductor device.

In one aspect of the present disclosure, there is provided a packaging unit for direct cooling of a semiconductor device including a substrate made of a material for manufacturing the semiconductor device, having a material layer for forming the semiconductor device stacked on one side thereof, and a flow channel through which a cooling fluid flows formed on the other surface thereof to enable direct cooling of the semiconductor device using the cooling fluid, a packaging block disposed at a position spaced apart from the substrate for packaging of the semiconductor device, electrically connected to the semiconductor device using an electrode, and insulated from the semiconductor device using the electrode disposed on an insulating block, and a heat sink unit disposed below the packaging block and including a flow path forming portion in which a flow path communicating with the flow channel of the substrate is formed.

In the flow path forming portion, an inflow line until the cooling fluid flows into the flow channel of the substrate and a discharge line until the cooling fluid is discharged after flowing into the flow channel may be formed to be partitioned from each other, so that the cooling fluid flowing into the inflow line is configured to pass through the flow channel of the substrate without being directly discharged to the discharge line.

The inflow line and the discharge line of the flow path forming portion may include a flow channel corresponding region provided in a part corresponding to the flow channel of the substrate, and arranged in a partitioned state.

The heat sink unit may include a manifold having a flow path forming portion including the flow channel corresponding region formed therein and a cover member interposed between the packaging block and the manifold to close the inflow line and the discharge line of the manifold other than the flow channel corresponding region.

The material layer may include gallium nitride (GaN).

The flow channel may be formed in an engraved pattern structure.

The packaging unit may further include metal coating layers coated with a metal material for bonding coupling, on one region of the substrate and the heat sink unit, respectively.

The heat sink unit and the packaging block may be integrally formed by a 3D printing method.

In another aspect of the present disclosure, there is provided a method of manufacturing a packaging unit for direct cooling of a semiconductor device including a preparation step of stacking a material layer for forming the semiconductor device on one surface of a substrate made of a material including silicon, a device forming step of forming a semiconductor device by performing a semiconductor process on the material layer, a channel forming step of forming a flow channel through which a cooling fluid flows on the other surface of the substrate to enable direct cooling of the semiconductor device using the cooling fluid, a wiring step of disposing a packaging block at a position spaced apart from the substrate for packaging of the semiconductor device, and electrically connecting an electrode placed on the packaging block to the semiconductor device, and a combining step of arranging a heat sink unit having the flow path forming portion in which a flow path communicating with the flow channel of the substrate is formed, below the packaging block, and combining the substrate with the heat sink unit.

The method may further include a step of performing metal coating on one region of the heat sink unit and the substrate for bonding coupling.

The present disclosure may provide a packaging unit for direct cooling of a semiconductor device which forms a flow channel through which a cooling fluid can flow in a substrate for forming the semiconductor device, and provides a heat sink unit having a flow path structure communicating with the flow channel of the substrate on a packaging block disposed to surround the semiconductor device for packaging the semiconductor device, and thus the substrate on which the device is to be formed can be directly cooled without using an indirect cooling method using a TIM, thereby improving the thermal management efficiency of the semiconductor device and expecting improvement of product performance accordingly.

The present disclosure may also provide a packaging unit for direct cooling of a semiconductor device which forms a flow path structure for implementing direct cooling of the semiconductor device by using a configuration used for packaging of the semiconductor device as the heat sink unit is provided on the packaging block, thereby achieving simplification of the structure and slimming of the product along with the improvement of the thermal management efficiency of semiconductor device.

### BRIEF DESCRIPTION OF THE DRAWINGS

FIG. 1 is a perspective view of a packaging unit for direct cooling of a semiconductor device according to an embodiment of the present disclosure.

FIG. 2 is an exploded perspective view of an embodiment of the present disclosure.

FIG. 3 is a bottom perspective view showing a substrate and a packaging block employed in an embodiment of the present disclosure.

FIG. 4 is a cross-sectional view taken along IV-IV of FIG. 1.

FIG. 5 is a diagram illustrating a flow process of a cooling fluid of an embodiment of the present disclosure.

FIG. 6 is a diagram illustrating a molding process of an embodiment of the present disclosure.

FIG. 7 is an exploded perspective view of a packaging unit for direct cooling of a semiconductor device according to another embodiment of the present disclosure.

FIG. 8 is a cross-sectional view of another embodiment of the present disclosure.

### DETAILED DESCRIPTION

In order to clarify the understanding of the present disclosure in the following description, descriptions of well-known technology of the features of the present disclosure will be omitted. The following embodiments are detailed descriptions to help the understanding of the present disclosure, and do not to limit the scope of the present disclosure. Accordingly, equivalent inventions performing the same functions as those of the present disclosure will also fall within the scope of the present disclosure.

In addition, in the following description, the same reference numeral mean the same configuration, and unnecessary redundant descriptions and descriptions of well-known technologies will be omitted. In addition, the description of each embodiment of the present disclosure that overlaps with the description of the technology that is the background of the invention will also be omitted.

Hereinafter, a packaging unit for direct cooling of a semiconductor device according to an embodiment of the present disclosure will be described in detail with reference to the accompanying drawings.

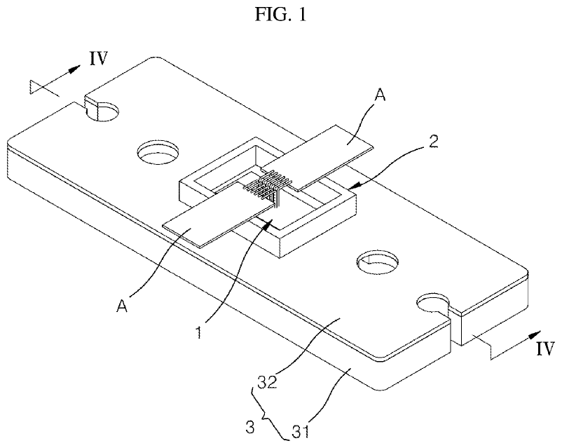

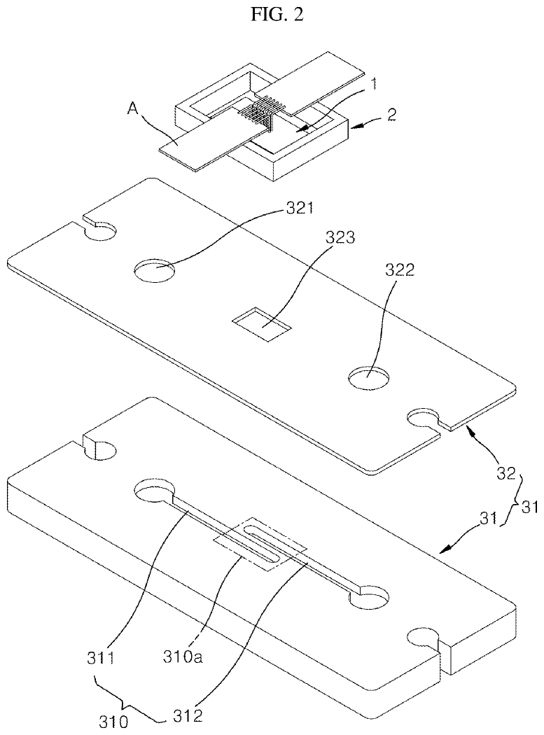

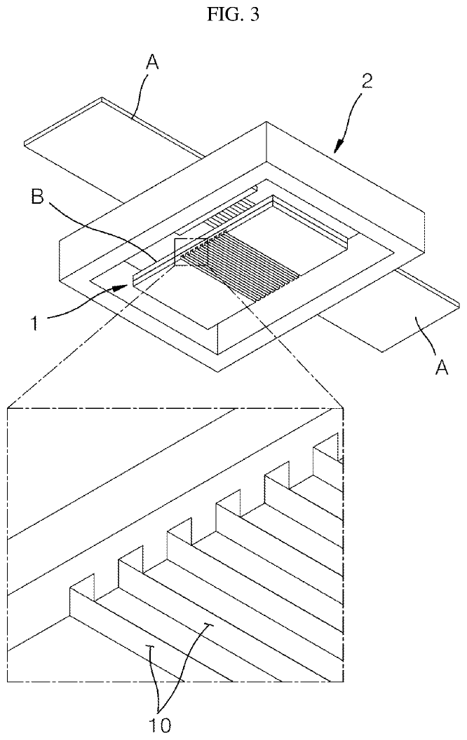

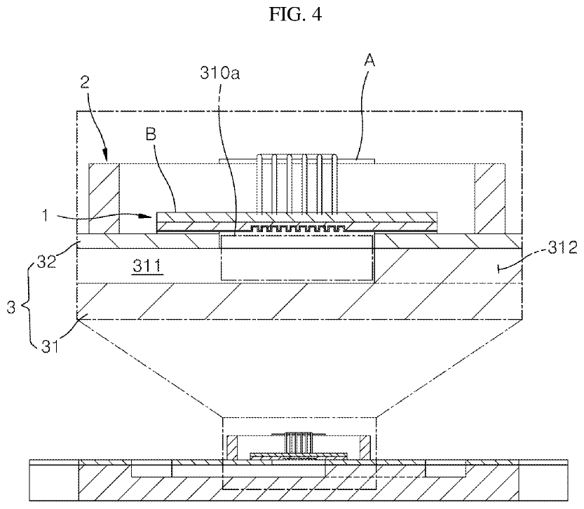

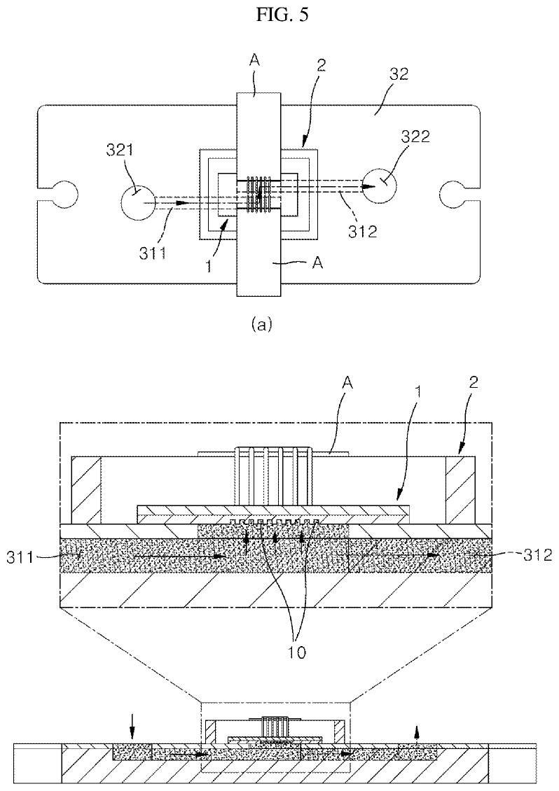

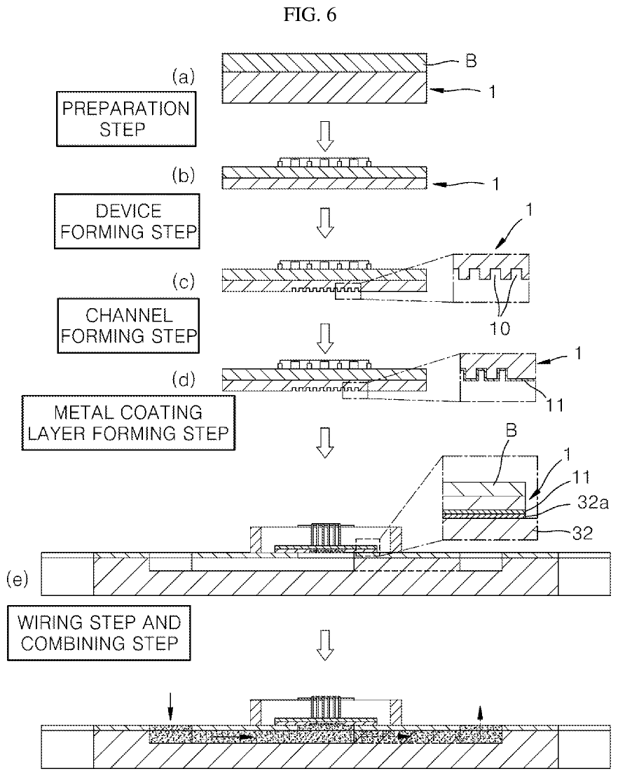

FIG. 1 is a perspective view of a packaging unit for direct cooling of a semiconductor device according to an embodiment of the present disclosure, FIG. 2 is an exploded perspective view of an embodiment of the present disclosure, FIG. 3 is a bottom perspective view showing a substrate and a packaging block employed in an embodiment of the present disclosure, FIG. 4 is a cross-sectional view taken along IV-IV of FIG. 1, FIG. 5 is a diagram illustrating a flow process of a cooling fluid of an embodiment of the present disclosure, and FIG. 6 is a diagram illustrating a molding process of an embodiment of the present disclosure.

As shown in these drawings, the packaging unit for direct cooling of the semiconductor device according to an embodiment of the present disclosure includes a substrate 1, a packaging block 2, and a heat sink unit 3.

The substrate 1 corresponds to a wafer for manufacturing the semiconductor device, is made of a material for manufacturing the semiconductor device, such as Si or SiC, and has a material layer B for forming the semiconductor device stacked on one surface of the substrate 1 as shown in (a) of FIG. 6, and a flow channel 10 through which the cooling fluid flows formed on the other surface of the substrate 1 as shown well in FIG. 3, which enables direct cooling of the semiconductor device using the cooling fluid.

The substrate 1 employed in the present embodiment is configured to be integrally formed of a single material including silicon, but the present disclosure is not limited thereto, and, for example, may also be configured in a structure in which a base layer for forming the semiconductor device and a channel layer for forming the flow channel of the cooling fluid are separately manufactured and then combined with each other. According to the embodiment, the base layer is made of the material including silicon and has a material layer for forming the semiconductor device stacked on one surface of the base layer, the channel layer B is stacked on the other surface of the base layer and has the flow channel through which the cooling fluid flows formed to enable direct cooling of the semiconductor device using the cooling fluid.

As well shown in FIGS. 3 and 4, the packaging block 2 is disposed to surround the substrate 1 at a position spaced apart from the substrate 1 for packaging of the semiconductor device, is made of an insulating material such as ceramic, and has an electrode An electrically connected to the semiconductor device through wiring placed thereon.

The heat sink unit 3 is disposed below the packaging block 2 and includes a flow path forming portion 310 in which a flow path communicating with the flow channel 10 of the substrate 1 is formed, so that the cooling fluid supplied from the outside may be introduced into the flow channel 10 of the substrate 1 through the flow path forming portion 310.

The packaging unit for direct cooling of the semiconductor device according to an embodiment of the present disclosure having the configuration above may form the flow channel 10 through which the cooling fluid can flow in the substrate 1 for forming the semiconductor device, and provide the heat sink unit 3 having a flow path structure communicating with the flow channel 10 of the substrate on the packaging block 2 disposed to surround the semiconductor device for packaging the semiconductor device, and thus the substrate 1 on which the device is to be formed may be directly cooled without using an indirect cooling method using a thermal interfacial material (TIM), thereby improving the thermal management efficiency of the semiconductor device and expecting improvement of product performance accordingly.

The packaging unit for direct cooling of the semiconductor device according to an embodiment of the present disclosure may also form a flow path structure for implementing direct cooling of the semiconductor device by using a configuration used for packaging of the semiconductor device as the heat sink unit 3 is provided on the packaging block 2, thereby achieving simplification of the structure and slimming of the product along with the improvement of the thermal management efficiency of semiconductor device.

The flow path forming portion 310 of the heat sink unit 3 employed in the present embodiment may be formed in various structures or pattern shapes communicating with the flow channel 10 of the substrate 1, but as shown in FIGS. 2 and 4, an inflow line 311 until the cooling fluid flows into the flow channel 10 of the substrate 1 and a discharge line 312 until the cooling fluid is discharged after flowing into the flow channel 10 are formed to be partitioned from each other in the flow path forming portion, so that a discharge path of the heated fluid by passing through the flow channel 10 and an inflow path of a new fluid in a low temperature state into the flow channel 10 are distinguished, and thus the cooling efficiency may be further improved.

According to the configuration, the cooling fluid flowing into the inflow line 311 is configured to pass through the flow channel 10 of the substrate 1 without being directly discharged to the discharge line 312, and thus the cooling efficiency of the device formed on the substrate 1 may be further improved.

As well shown in FIGS. 2 and 5, the inflow line 311 and the discharge line 312 of the flow path forming portion 310 include a flow channel corresponding region 310a provided in a part corresponding to the flow channel 10 of the substrate 1, and arranged in a partitioned state, so that the cooling fluid is configured to intensively exert a cooling function in the flow channel corresponding region 310a, thereby further improving the cooling efficiency.

The heat sink unit 3 may be integrally formed of a single material, but as shown in FIGS. 1 and 2, may also be configured such that two units including a manifold 31 and a cover member 32 are separately manufactured and then combined with each other.

The manifold 31 has the flow path forming portion 310 including the flow channel corresponding region 310a formed therein, and the cover member 32 is interposed between the packaging block 2 and the manifold 31 to close the inflow line 311 and the discharge line 312 of the manifold 31 other than the flow channel corresponding region 310a.

In addition, an inflow port 321 through which the cooling fluid flows, a discharge port 322 through which the cooling fluid is discharged, and a through hole 323 formed between the inflow port 321 and the discharge port 322 in a position corresponding to the flow channel corresponding region 310a of the manifold 31 are formed in the cover member 32.

The material layer B placed on the substrate 1 may be formed of various materials, but gallium nitride (GaN) is adopted in the present embodiment.

The flow channel 10 of the substrate 1 may be configured in an embossed pattern structure protruding from a plane, but in the present embodiment, as well shown in FIGS. 3 and 4, is formed in an engraved pattern structure.

Meanwhile, as well shown in FIGS. 4 and 6, the present embodiment further includes metal coating layers 11 and 32a coated with a metal material for bonding coupling, on one region of the substrate 1 and the heat sink unit 3, respectively, thereby securing a greater bonding force between the substrate 1 and the heat sink unit 3 of different materials.

The heat sink unit 3 and the packaging block 2 employed in the present embodiment are configured to be manufactured separately and then combined with each other, but the present disclosure is not limited thereto, and may be integrally formed, for example, by a 3D printing method.

Hereinafter, a method of manufacturing the packaging unit for direct cooling of the semiconductor device according to an embodiment of the present disclosure will be described in detail with reference to FIG. 6.

As shown in FIG. 6, the present embodiment includes a preparation step, a device forming step, a channel forming step, a wiring step, and a combining step.

In the preparation step, a process of stacking the material layer B for forming the semiconductor device on one surface of the substrate 1 made of a material including silicon is performed (see (a) of FIG. 6), and in the device forming step, a process of forming the semiconductor device by performing a semiconductor process on the material layer B is performed (see of (b) of FIG. 6).

In the channel forming step, the flow channel 10 through which the cooling fluid flows is formed on the other surface of the substrate 1 to enable direct cooling of the semiconductor device using the cooling fluid (see (c) of FIG. 6), and in the wiring step, the packaging block 2 is disposed at a position spaced apart from the substrate 1 for packaging of the semiconductor device, and the electrode A placed on the packaging block 2 is electrically connected to the semiconductor device (see (e) of FIG. 6).

In the combining step, a process of arranging the heat sink unit 3 having the flow path forming portion 310 in which a flow path communicating with the flow channel 10 of the substrate 1 is formed, below the packaging block 2, and combining the substrate 1 with the heat sink unit 3 is performed (see of (d) of FIG. 6).

In the method of manufacturing the packaging unit for direct cooling of the semiconductor device according to the present embodiment having such a configuration, the flow channel 10 that enables direct cooling by the cooling fluid is formed on the substrate 1 on which the semiconductor device is formed, and a cooling fluid flow path communicating with the flow channel 10 on the packaging block 2 disposed to surround the substrate 1 for packaging the semiconductor device, and thus the structure of the packaging unit of the semiconductor device may be simplified, and contribution to the improvement of product performance according to improvement of the cooling efficiency may be expected.

In addition, the method of manufacturing the packaging unit for direct cooling of the semiconductor device according to the present embodiment, as well shown in (d) and (e) of FIG. 6, further includes a step of performing metal coating on one region of the heat sink unit 3 and the substrate 1 for bonding coupling, and thus a greater bonding force between the substrate 1 and the heat sink unit 3 may be secured.

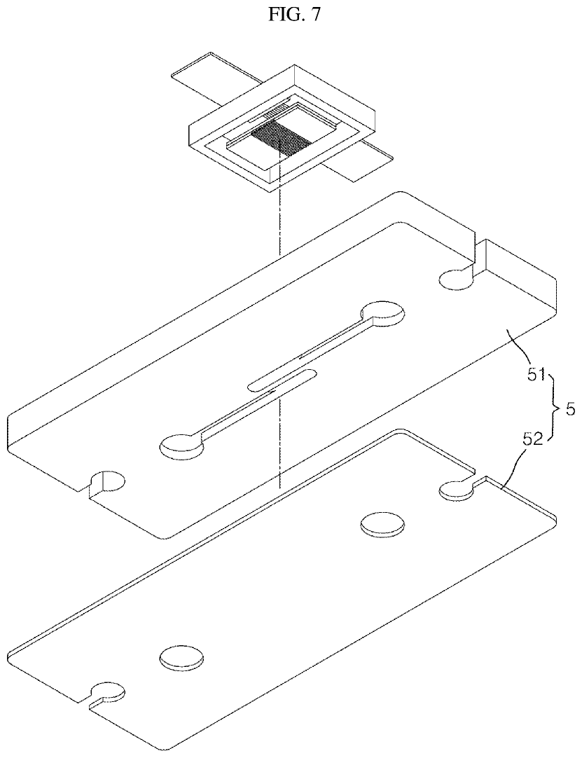

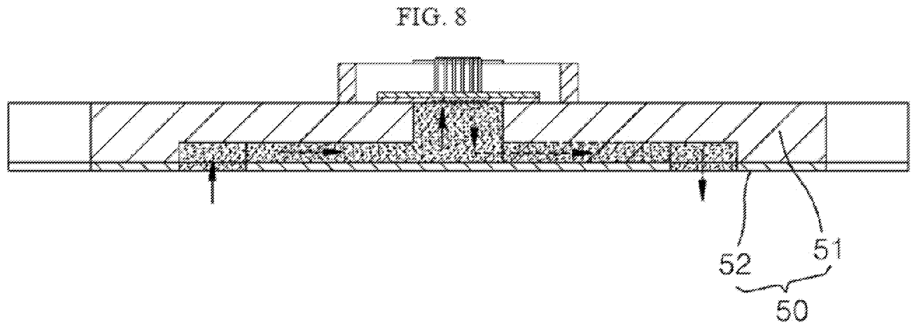

Meanwhile, FIG. 7 is an exploded perspective view of a packaging unit for direct cooling of a semiconductor device according to another embodiment of the present disclosure, and FIG. 8 is a cross-sectional view of another embodiment of the present disclosure.

As shown in these drawings, the present embodiment adopts a structure in which a cooling fluid flows from a lower side of a heat sink unit to an upper side as opposed to the above-described embodiment in which the cooling fluid flows from the upper side of the heat sink unit to the lower side.

That is, according to the present embodiment, a cover member 52 constituting a heat sink unit 5 is disposed on the lower side, and a manifold 51 constituting the heat sink unit 5 is disposed between the cover member 52 and a substrate, and thus an inflow direction of the cooling fluid may be implemented opposite to that of the above-described embodiment.

Although various embodiments of the present disclosure have been described above, the present embodiment and the drawings attached to the present specification merely clearly present a part of the technical idea included in the present disclosure, and it will be obvious that all modifications and specific embodiments that can be easily inferred by those skilled in the art within the scope of the technical idea included in the specification and drawings of the present disclosure are included in the scope of the present disclosure.

What is claimed is:

1. A method of manufacturing a packaging unit for direct cooling of a semiconductor device, the method comprising:
a preparation step of stacking a material layer for forming the semiconductor device on one surface of a substrate made of a material including silicon;
a device forming step of forming a semiconductor device by performing a semiconductor process on the material layer;
a channel forming step of forming a flow channel through which a cooling fluid flows on the other surface of the substrate to enable direct cooling of the semiconductor device using the cooling fluid;
a wiring step of disposing a packaging block at a position spaced apart from the substrate for packaging of the semiconductor device, and electrically connecting an electrode placed on the packaging block to the semiconductor device; and
a combining step of arranging a heat sink unit having a flow path forming portion in which a flow path communicating with the flow channel of the substrate is formed, below the packaging block, and combining the substrate with the heat sink unit.

2. The method of claim 1, further comprising a step of performing metal coating on one region of the heat sink unit and the substrate for bonding coupling.

3. The method of claim 1, wherein the substrate is integrally formed of a single material including silicon.

4. The method of claim 1, wherein the substrate includes a base layer made of a material including silicon and having a material layer for forming the semiconductor device stacked on one surface of the base layer, and a channel layer stacked on the other surface of the base layer and having the flow channel through which the cooling fluid flows formed to enable direct cooling of the semiconductor device using the cooling fluid.

5. The method of claim 1, wherein, in the flow path forming portion, an inflow line until the cooling fluid flows into the flow channel of the substrate and a discharge line until the cooling fluid is discharged after flowing into the flow channel are formed to be partitioned from each other, so that the cooling fluid flowing into the inflow line is configured to pass through the flow channel of the substrate without being directly discharged to the discharge line.

6. The method of claim 5, wherein the inflow line and the discharge line of the flow path forming portion include a flow channel corresponding region provided in a part corresponding to the flow channel of the substrate, and arranged in a partitioned state.

7. The method of claim 6, wherein the heat sink unit includes a manifold having a flow path forming portion including the flow channel corresponding region formed therein and a cover member interposed between the packaging block and the manifold to close the inflow line and the discharge line of the manifold other than the flow channel corresponding region.

8. The method of claim 1, wherein the material layer includes gallium nitride (GaN).

9. The method of claim 1, wherein the flow channel is formed in an engraved pattern structure.

10. The method of claim 7, wherein the heat sink unit and the packaging block are integrally formed by a 3D printing method.
